(19) United States
(12) Patent Application Publication
(10) Pub. No.: US 2010/0224386 A1
(43) Pub. Date: Sep. 9, 2010

(54) ELECTRONIC PARTS

(76) Inventor: Tam-Lim Oh, Jeju-do (KR)

Correspondence Address: BIRCH STEWART KOLASCH & BIRCH, PO BOX 747, FALLS CHURCH, VA, 22040-0747, US

(21) Appl. No.: 12/377,399

(22) PCT Filed: Dec. 18, 2006
(86) PCT No.: PCT/KR2006/005540

§ 371 Date: Feb. 13, 2009

(51) Int. Cl. H05K 5/00

(52) U.S. Cl. 174/50

(57) ABSTRACT

The present invention is relates to an electronic part. The electronic part of the present invention has an external appearance defined by a case 20. The case 20 is formed with a through-hole 22 for allowing an internal space of the case to communicate with the outside, and a terminal 24 is installed through the through-hole 22. The terminal 24 electrically connects devices within the case with the outside. The case 20 may be manufactured from a plurality of pieces. Sealants 26 are applied to a gap between the through-hole 22 of the case 20 and the terminal 24 and around the through-hole 22 and also to portions where the plurality of pieces of the case 20 are combined together. Flavonoid is added as an insecticide component to the sealant 26.

### TECHNICAL FIELD

The present invention relates to an electronic part, and more particularly, to an electronic part electrically connected to the outside to receive and transmit electrical signals from and to the outside.

### BACKGROUND ART

FIG. 2 shows a timer used in a refrigerator as an electronic part according to a related art. As shown in the figure, a case 2 defines the external appearance and framework of the timer. A plurality of through-holes 4 are formed on one surface of the case 2. A plurality of terminals 6 are installed within the case 2 such that they can protrude toward the outside through the through-holes 4. The terminals 6 are used to transfer electrical signals between the timer and the outside.

However, the aforementioned related art electronic part has the following problems.

That is, the case 2 is generally injection molded and each of the terminals 6 is formed of conductive metallic materials through press working. Due to tolerances occurring when manufacturing the case 2 and the terminal 6, however, a constant gap 2G may be created between the through-hole 4 and the terminal 6 as clearly shown in FIG. 2. In other words, the width w′ of the terminal 6 is generally smaller than the width w of the corresponding through-hole 4, and thus, the aforementioned gap is created.

If the gap 2G is created between the through-hole 4 and the terminal 6, some problems of the operation of the electronic part may be created. That is, foreign materials may be introduced into the case 2 through the gap 2G, and particularly, insects such as ants are likely to come into the case 2 through the gap 2G. These foreign materials or insects such as ants may do damage to the interior of the electronic part, which in turn cannot be normally operated.

### DISCLOSURE

### Technical Problem

The present invention has been conceived to solve the aforementioned problem in the prior art. Accordingly, an object of the present invention is to prevent foreign materials from being introduced into a case of an electronic part, and particularly, to prevent insects such ants from coming into the case of the electronic part.

### Technical Solution

According to an aspect of the present invention for achieving the above object, there is provided an electronic part, comprises a case for defining an external appearance of the electronic part, the case being formed with a predetermined spaced therein and with a plurality of through-holes at one surface thereof to allow the space to communicate with the outside; terminals of which portions protrude to the outside through the through-holes to transfer electrical signals; and sealants containing insecticide components and applied to gaps between the terminals and the through-holes and around edges of the through-holes.

The case is manufactured from a plurality of pieces and sealants containing insecticide components are applied to portions where the pieces of the case are combined together.

The sealants are applied to the gaps and around the through-holes or to the combined portions of the case in the form of coating layers.

The sealants are filled into the gaps between the through-holes and the terminals.

The insecticide component of the sealant is flavonoid.

The flavonoid is Ginkgo biloba extract.

The case defines an external appearance of a timer of a refrigerator.

### ADVANTAGEOUS EFFECTS

According to the present invention so configured, it is possible to prevent foreign materials from being introduced into a case of an electronic part, and particularly, to effectively prevent insects such as ants from coming into the case of the electronic part. Therefore, there is an advantage in that operating reliability and durability of the electronic part used in a product such as a refrigerator having an environment where insects such as ants may live can be enhanced.

### DESCRIPTION OF DRAWINGS

FIG. 1 is a perspective view of an electronic part according to a preferred embodiment of the present invention. FIG. 2 is a perspective view showing the configuration of a related art electronic part.

### BEST MODE

Hereinafter, an electronic part according to a preferred embodiment of the present invention will be described in detail with reference to the accompanying drawings.

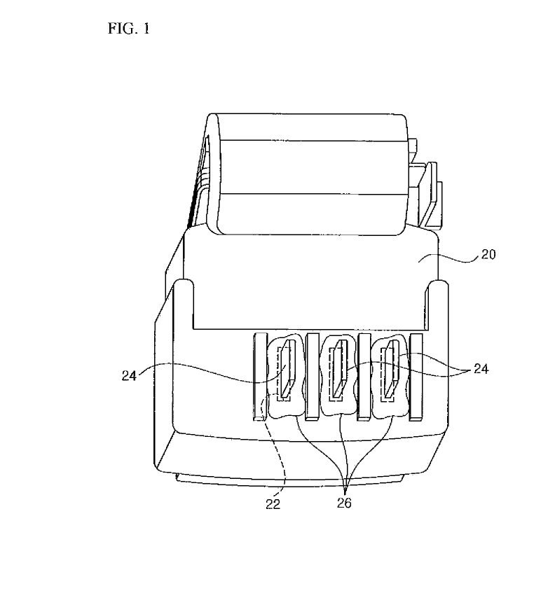

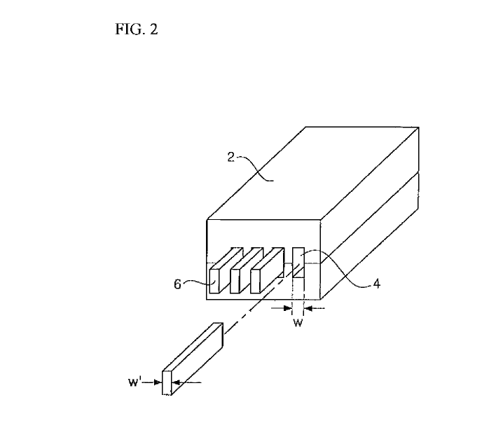

As shown in FIG. 1, a case 20 defines the external appearance and framework of an electronic part. The case 20 is made of a synthetic resin and is generally manufactured from a plurality of pieces. That is, the plurality of pieces are combined into a final product to define a predetermined space in the product.

A through-hole 22 is bored through one surface of the case 20. The through-hole 22 serves to allow the internal space of the case 20 to communicate with the outside. In the preferred embodiment of the present invention, a plurality of through-holes 22 may be formed.

A plurality of terminals 24 for electrically connecting the inside and outside of the case 20 are installed through the through-holes 22. Each of the terminals 24 is generally formed of a conductive metallic material. The terminal 24 is used to electrically connect devices in the case 20 and the outside. In general, a printed circuit board on which a variety of devices are mounted is installed within the case 20. In this case, the terminals are also mounted on the printed circuit board. However, the terminals are not necessarily mounted on the printed circuit board. Each of the terminals 24 protrudes outwardly from the case 20 through the through-hole 22 by a predetermined length.

Sealants 26 are filled on a front surface of the case 20 corresponding to an edge of the through-hole 22 and between the terminal 24 and the through-hole 22. Each of the sealants 26 serves to prevent foreign materials, small insects or the like from being introduced into the case 20 through the gap between the through-hole 22 and the terminal 24. It is apparent that the sealants 26 may be applied to apertures of the case 20, e.g. portions where the constituent pieces of the case 20 are combined together, or between the terminal 24 and the through-hole 22 to prevent the foreign materials from passing through the gaps and to maintain the case 20 in an airtight or watertight state.

Here, a gap between the through-hole 22 and the terminal 24 may be completely filled with the sealant 26. Alternatively, the gap may be filled with the sealant to a certain extent that the gap can be merely blocked by the sealant. For example, the sealant is formed to a certain degree that it is applied onto the surface of the case 20, i.e. a coating layer is formed on the surface of the case 20, but a whole gap needs not be completely filled with the sealant.

Further, insects such as small bugs may do damage to the sealant 26 and come through the case 20, To prevent this, an appropriate proportion of Ginkgo biloba extract is preferably added to the sealant 26. For reference, the Ginkgo biloba extract contains germicide and insecticide components called ‘flavonoid’. That is, the flavonoid is used to kill or suppress lavae of various small insects, fungi parasitic to plants, viruses and the like.

As described above, if an appropriate proportion of the Ginkgo biloba extract containing the flavonoid is added to the sealant 26, small insects such as ants do not approach the gap between the through-hole 22 and the terminal 26 due to flavonoid components.

Here, an amount of the Ginkgo biloba extract added to the sealant 26 may be determined to a certain degree that it has no influence on an airtight or watertight effect but has a predetermined germicide and insecticide effect.

Although it has been described in the illustrated embodiment that the gap between the terminal 24 and the through-hole 22 of the case 20 is filled with the sealant 26 which in turn is applied around the gap, the present invention is not necessarily limited thereto. That is, if the case 20 is manufactured from a plurality of pieces, the sealants 26 may be applied to portions where the pieces are combined together.

Hereinafter, the operation of the electronic part according to the present invention so configured will be explained in detail.

The electronic part of the present invention is assembled in such a manner that devices such as a printed circuit board are placed in a space defined within the case 20 and the terminals 24 are exposed to the outside of the case 20 through the through-holes 22. Then, the gaps or combined portions of the case 20 are filled and coated with the sealants 26. For example, the sealants 26 with the Ginkgo biloba extract added thereto are filled in the gaps between the through-holes 22 and the terminals 24 and are applied around the gaps. Here, the sealants 26 may be filled or coated around portions adjacent to the through-holes 22 and the terminals 24.

If such a sealant 26 is employed in the present invention, the small insects such as ants cannot come into the electronic part through the gaps or combined portions of the case 20. Of course, even though the sealant 26 is thinly filled or applied, it is less likely that the small insects such as ants break through the sealant 26 and come into the case 20. The reason is that since the Ginkgo biloba extract containing the insecticide component is added to the sealant 26, the ants and the like do not approach a portion where the sealant 26 is applied.

Since the sealants 26 serve to block the gaps or combined portions of the case 20 in the present invention, they can prevent foreign materials from being introduced into the case 20. In addition, since small insects such as ants do not approach the sealant 26 due to the insecticide components contained in the sealant 26, it is possible to prevent the small insects such as ants from coming into the case 20 through the gaps.

In order to solve the aforementioned problems that may occur near the gaps or combined portions of the case 20 of the electronic part, it is sufficient to only fill or apply fluid sealants 26 in or near the gaps. Thus, other components need not be added to the terminals 24 or case 20. Accordingly, manufacturing costs can be reduced and the enhanced mass production can be also obtained.

For reference, a timer for a refrigerator may be used in the present invention as an example of an electronic part. The timer is used to adjust a defrost time when performing a refrigerating cycle in the refrigerator. Since a refrigerator is commonly utilized indoors and a machine room of the refrigerator in which the timer is installed is a place where the temperature is relatively high, there may be other harmful insects in addition to the ants. Therefore, it is possible to prevent insects such as ants from approaching the timer by using the sealant containing the flavonoid as described above in the present invention.

The scope of the present invention is not limited to the aforementioned embodiment but defined by the appended claims. It is also apparent to those skilled in the art that a variety of modifications and changes can be made thereto within the scope of the appended claims.

### INDUSTRIAL APPLICABILITY

According to the present invention so configured, since sealants containing flavonoid components can be utilized to seal gaps or combined portions of a case of an electronic part, it is possible to prevent foreign materials or insects such as ants from being introduced into the case of the electronic part. Therefore, there is an advantage in that the electronic part can be prevented from being damaged by the foreign materials or insects such as ants, whereby operating reliability and durability of the electronic part can be enhanced.

1. An electronic part, comprising:
a case for defining an external appearance of the electronic part, the case being formed with a predetermined spaced therein and with a plurality of through-holes at one surface thereof to allow the space to communicate with the outside;
terminals of which portions protrude to the outside through the through-holes to transfer electrical signals; and
sealants containing insecticide components and applied to gaps between the terminals and the through-holes and around edges of the through-holes.

2. The electronic part as claimed in claim 1, wherein the case is manufactured from a plurality of pieces and sealants containing insecticide components are applied to portions where the pieces of the case are combined together.

3. The electronic part as claimed in claim 2, wherein the sealants are applied to the gaps and around the through-holes or to the combined portions of the case in the form of coating layers.

4. The electronic part as claimed in claim 2, wherein the sealants are filled into the gaps between the through-holes and the terminals.

5. The electronic part as claimed in any one of claims 1 to 4, wherein the insecticide component of the sealant is flavonoid.

6. The electronic part as claimed in claim 5, wherein the flavonoid is Ginkgo biloba extract.

7. The electronic part as claimed in claim 6, wherein the case defines an external appearance of a timer of a refrigerator.
